(19) United States
(12) Patent Application Publication
(10) Pub. No.: US 2022/0013983 A1
(43) Pub. Date: Jan. 13, 2022

(54) VEHICLE DATA COMMUNICATION CABLE ASSEMBLY AND SYSTEM

(71) Applicant: Mobix Labs, Inc., Irvine, CA (US)

(72) Inventors: Devang Parekh, Castro Valley, CA (US); David Miller, San Francisco, CA (US)

(21) Appl. No.: 16/923,472

(22) Filed: Jul. 8, 2020

(51) Int. Cl. H01S 5/06; H01S 5/068; H04B 10/40; H04B 10/50; G02B 6/44; G02B 6/38

(52) U.S. Cl. CPC H01S 5/0617; H01S 5/06808; H04B 10/40; G02B 6/3887; G02B 6/4416; G02B 6/3817; H04B 10/504

(57) ABSTRACT

A vehicle data communication system including a first vehicle subsystem; a second vehicle subsystem; and a data communication cable assembly including a first connector connected to the first vehicle subsystem; a second connector connected to the second vehicle subsystem; and a cable including opposite ends securely attached to the first and second connectors, respectively, wherein the cable comprises one or more optical transmission mediums configured to transmit a first optical data signal from the first connector to the second connector. The vehicle data communication system may include a set of cascadable cable assemblies for transmission of optical data signals between the first and second vehicle subsystems.

### FIELD

Aspects of the present disclosure relate generally to data communication cables and systems, and in particular, to various data communication cable assemblies applicable to vehicles (e.g., automotive) data communication applications.

### BACKGROUND

High speed digital communications are widely used in cars today, supporting features like integrated sensors, video playback, driver assistance systems, and autonomous driving. As automotive technologies continue to rapidly evolve, the data rate requirements for these digital systems increase exponentially.

Many previous digital communication standards in the automotive market—Controller Area Network (CAN), Local Interconnect Network (LIN), and FlexRay—have been historically for low data rate real-time transfers of data, such as results from power train sensors, vehicle body commands (e.g., door locks, windows, heating and cooling), or passenger safety systems. With the growing need for higher data rate devices, including real-time video for autonomous vehicles, automotive systems are venturing into the Gigabit per second (Gbps) speed domain.

Another digital communication area-of-interest concerns automotive environments having strict requirements for temperature and electromagnetic interference (EMI). Data communication systems for automotive use are generally constructed using twisted pair copper wiring. Copper wiring is inexpensive and generally easy to use, but suffers from signal degradation at higher data rates. Additionally, high speed data communication over copper wires can create electrical interference above specified automotive regulatory thresholds.

For example, Automotive Ethernet and Media Oriented Systems Transport (MOST) use specialized techniques to reduce EMI. However, their data transmission speeds are currently limited to rates of less than one (1) Gbps. Due to the heightened temperature and EMI requirements, the communication speed of automotive systems tends to lag that of their non-automotive commercial and industrial counterparts.

### SUMMARY

The following presents a simplified summary of one or more embodiments in order to provide a basic understanding of such embodiments. This summary is not an extensive overview of all contemplated embodiments, and is intended to neither identify key or critical elements of all embodiments nor delineate the scope of any or all embodiments. Its sole purpose is to present some concepts of one or more embodiments in a simplified form as a prelude to the more detailed description that is presented later.

An aspect of the disclosure relates to a vehicle data communication system including a first vehicle subsystem; a second vehicle subsystem; and a data communication cable assembly including a first connector connected to the first vehicle subsystem; a second connector connected to the second vehicle subsystem; and a cable including opposite ends securely attached to the first and second connectors, respectively, wherein the cable comprises one or more optical transmission mediums configured to transmit a first optical data signal from the first connector to the second connector.

Another aspect of the disclosure relates to a vehicle data communication system including a first vehicle subsystem; a second vehicle subsystem; a first data communication cable assembly including a first connector connected to the first vehicle subsystem, a second connector, and a first cable including opposite ends securely attached to the first and second connectors, respectively, wherein the first cable comprises a first set of one or more optical data transmission mediums configured to transmit a first set of one or more optical data signals between the first and second connectors; and a second data communication cable assembly including a third connector, a fourth connector connected to the second vehicle subsystem; and a second cable including opposite ends securely attached to the third and fourth connectors, respectively, wherein the second cable comprises a second set of one or more optical data transmission mediums configured to transmit the first set of one or more optical data signals or a second set of one or more optical data signals between the third and fourth connectors.

To the accomplishment of the foregoing and related ends, the one or more embodiments include the features hereinafter fully described and particularly pointed out in the claims. The following description and the annexed drawings set forth in detail certain illustrative aspects of the one or more embodiments. These aspects are indicative, however, of but a few of the various ways in which the principles of various embodiments may be employed and the description embodiments are intended to include all such aspects and their equivalents.

### BRIEF DESCRIPTION OF THE DRAWINGS

FIG. 1 illustrates a block diagram of an exemplary vehicle data communication system in accordance with another aspect of the disclosure.

FIG. 2 illustrates a block diagram of another exemplary vehicle data communication system in accordance with another aspect of the disclosure.

FIG. 3 illustrates a block diagram of another exemplary vehicle data communication system in accordance with another aspect of the disclosure.

FIG. 4A illustrates a block/schematic diagram of an exemplary data communication cable assembly configured for full-duplex data transmission over optical transmission mediums in accordance with another aspect of the disclosure.

FIG. 4B illustrates a block/schematic diagram of another exemplary data communication cable assembly configured for half-duplex, time division multiplexed (TDM) data transmission over at least one optical transmission medium in accordance with another aspect of the disclosure.

FIG. 4C illustrates a block/schematic diagram of another exemplary data communication cable assembly configured for full-duplex, wavelength division multiplexed (WDM) data transmission over at least one optical transmission medium in accordance with another aspect of the disclosure.

FIG. 5 illustrates a block/schematic diagram of an exemplary cascadable data communication cable assembly including one or more optical transmission mediums in accordance with another aspect of the disclosure.

FIG. 6A illustrates a block/schematic diagram of another exemplary vehicle data communication system including a set of data communication cable assemblies cascaded together to communicatively couple a pair of vehicle subsystems in accordance with another aspect of the disclosure.

FIG. 6B illustrates a block/schematic diagram of another exemplary vehicle data communication system including a set of data communication cable assemblies cascaded together to communicatively couple a pair of vehicle subsystems in accordance with another aspect of the disclosure.

FIG. 7A illustrates a block/schematic diagram of another exemplary cascadable data communication cable assembly including one or more optical transmission mediums in accordance with another aspect of the disclosure.

FIG. 7B illustrates a block/schematic diagram of another exemplary cascadable data communication cable assembly including one or more optical transmission mediums in accordance with another aspect of the disclosure.

FIG. 7C illustrates a block/schematic diagram of another exemplary cascadable data communication cable assembly including one or more optical transmission mediums in accordance with another aspect of the disclosure.

FIG. 8 illustrates a block diagram of another exemplary vehicle data communication system including a set of cascaded data communication cable assemblies in accordance with another aspect of the disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

Optical fiber communications produce significantly less EMI than copper wires and are more immune to external electrical interference, while providing higher data rates. In addition, optical cabling can be lighter and more flexible than copper cabling. Optical fiber cabling can provide the ability for automotive data communications to reach much higher speeds than they are presently equipped with, and it will allow for the next generation of demanding applications in entertainment, safety, sensors, and autonomous driving.

An active data communication cable assembly with optical transmission mediums (e.g., optical fibers) is presented that meets the temperature and electromagnetic compatibility (EMC) specifications for automotive use (e.g., Automotive Electronics Council (AEC), AEC-Q100 category 2 −40° C. to 105° C. or higher, and Federal Communications Commission (FCC) and Comité International Spécial des Perturbations Radioélectriques (CISPR) EMC requirements).

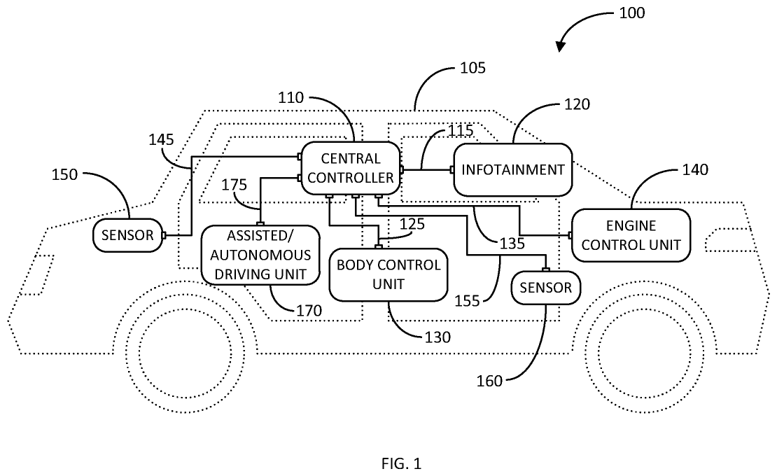

The active optical data communication cable assembly disclosed herein may be compatible with existing data communication standards, including, but not limited, to High Definition Multimedia Interface (HDMI), DisplayPort, Digital Visual Interface (DVI), and Universal Serial Bus (USB). The active optical data communication cable assembly can be used to link individual components, or it can be used in a system hierarchy to link between major subsystems within an automobile. The cable jacket is rated to the same or better operating temperature. The end connectors of the cable assemblies are compatible to the applicable ingress protection (“IP”) ratings for the application, including protection against dust and/or water. An example automotive system hierarchy with data links is shown in FIG. 1. The cable assemblies provide data connections between the major systems in an automotive environment (the “backbone”), or between individual components, including cameras, sensors, displays, smart antennas, and/or data loggers.

FIG. 1 illustrates a block diagram of an exemplary vehicle data communication system 100 in accordance with an aspect of the disclosure. In this example, the associated vehicle of the system 100 is an automobile 105. However, it shall be understood that such system 100 may be configured to facilitate data communication in other types of vehicles, such as airplanes, trains, buses, boats, ships, etc.

The vehicle data communication system 100 includes several data communication subsystems configured to generate, transmit, and/or receive data signals. Such vehicle subsystems may include a central controller 110, an infotainment subsystem 120, a body control unit 130, an engine control unit 140, a set of sensors 150 and 160, and an assisted and/or autonomous driving unit 170. These are just some examples of subsystems that may be in a vehicle or automobile. It shall be understood that vehicles or automobiles may be configured with a different set of subsystems.

The infotainment subsystem 120 communicates multimedia data (audio and/or video), information (e.g., automotive navigation information), entertainment data, and control information with the central controller 110 (and/or with other subsystem(s)) via an optical data communication cable assembly 115. The infotainment subsystem 120 may include a radio, optical multimedia disc player (e.g., compact disc (CD), digital versatile disc (DVD), BlueRay, etc.), Universal Serial Bus (USB) and/or Bluetooth connectivity (e.g., smart phone connectivity), global positioning system (GPS), steering wheel infotainment control subsystem, handsfree and/or voice infotainment control subsystem, etc.

The body control subsystem 130 communicates body control data with the central controller 110 (and/or with other subsystems) via an optical data communication cable assembly 125. Such body control data includes data related to control of internal and external lighting, automatic windows, power mirrors, power seats, door locks, access control, air conditioning, heater, seat heating and/or cooling systems, comfort control, safety (e.g., airbags), etc.

The engine control unit 140 communicates engine control data with the central controller 110 (and/or with other subsystem(s)) via an optical data communication cable assembly 135. Such engine control data includes information for controlling actuators of an internal combustion engine (or electrical engine) to ensure optimal engine performance. For example, such actuators may control air-fuel mixture, ignition timing, idle speed, fuel injection, valve control actuators, etc. Other engine control data includes sensor data, such as oxygen sensor data, throttle position (accelerator) sensor data, mass airflow (into the engine) data, engine coolant temperature sensor data, manifold pressure data, intake air temperature data, crank and/or cam shaft position sensor data, speed sensor data, knock sensor data, etc.

The assisted and/or autonomous driving unit 170 communicates assisted and/or autonomous control data with the central controller 110 (and/or with other subsystem(s)) via an optical data communication cable assembly 175. Such assisted and/or autonomous control data may include cruise control data, such as speed control (e.g., speed set, increase, decrease), speed sensor data, etc. Assisted and/or autonomous driving control data may also include collision avoidance sensor systems (e.g., cameras, radar-antennas, infrared (IR) sensors, etc.), automatic brake systems, navigation systems, speed limit detection systems, etc.

Various sensors, such as sensors 150 and 160, may communicate control sensor data with the central controller 110 (and/or with other subsystem(s)) via optical data communication cable assemblies 145 and 155, respectively.

As discussed, the optical data communication cable assemblies 115, 125, 135, 145, 155, and 175 of the vehicle data communication system 100 emit less electromagnetic interference than data communication cables that use wire or electrical conductors for transmitting data. This facilitates meeting the electromagnetic compatibility (EMC) specifications dictated by many automotive or vehicle regulation entities. The connectors of the optical data communication cable assemblies 115, 125, 135, 145, 155, and 175 may also be configured to comply with applicable ingress protection (“IP”) ratings, including protection against dust and/or water. Furthermore, the optical fibers and associated components of the optical data communication cable assemblies 115, 125, 135, 145, 155, and 175 may also be configured to comply with temperature range requirements specified by such automotive or vehicle regulation entities.

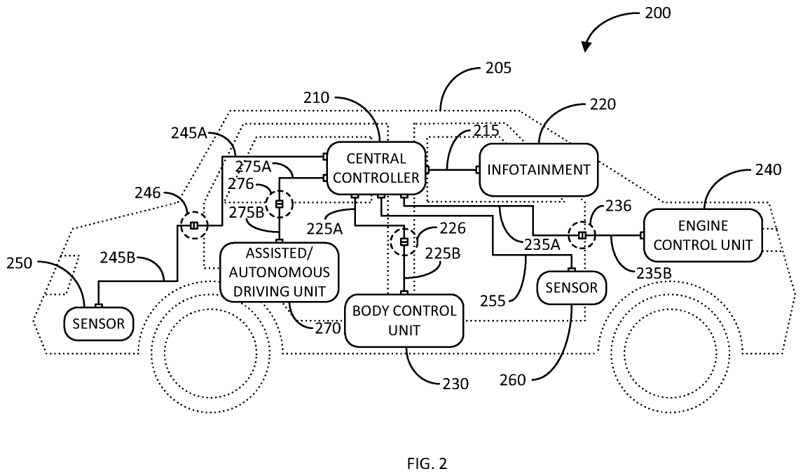

FIG. 2 illustrates a block diagram of another exemplary vehicle data communication system 200 in accordance with another aspect of the disclosure. The vehicle data communication system 200 is similar to vehicle data communication system 100, which includes an automobile 205 with many similar subsystems, such as a central controller 210, infotainment subsystem 220, body control unit 230, engine control unit 240, assisted/autonomous driving unit 270, and various sensors 250 and 260.

The vehicle data communication system 200 differs from vehicle data communication system 100 in that one or more of the optical data communication cable assemblies connecting two subsystems together may include a set of cascaded cable assemblies. For example, the optical data communication cable connecting the central controller 210 to the body control unit 230 may include a pair of cascaded optical data communication cable assemblies 225A and 225B. Similarly, the optical data communication cable connecting the central controller 210 to the engine control unit 240 may include a pair of cascaded optical data communication cable assemblies 235A and 235B. And, another example is the optical data communication cable connecting the central controller 210 to the sensor 250, which may include a pair of cascaded optical data communication cable assemblies 245A and 245B. Additionally, another example is the optical data communication cable connecting the central controller 210 to the sensor assisted/autonomous driving unit 270, which may include a pair of cascaded optical data communication cable assemblies 275A and 275B. Although in these examples, there are two cascaded cable assemblies between subsystems, it shall be understood that there may be more than two cable assemblies connecting subsystems together.

A use or advantage of such cascaded optical data communication cable assemblies is that the area in the vehicle 205 in which they connect to each may be more easily accessible by technicians (or other users) in order to test and troubleshoot the data communication system. For example, the optical communication cable assembly 225A connects to the optical communication cable assembly 225B at an area 226 of the vehicle 205 that may be easily accessible by a technician. Similarly, the optical communication cable assembly 235A connects to the optical communication cable assembly 235B at an area 236 of the vehicle 205 that may be easily accessible by a technician. Likewise, the optical communication cable assembly 245A connects to the optical communication cable assembly 245B at an area 246 of the vehicle 205 that may be easily accessible by a technician. And, the optical communication cable assembly 275A connects to the optical communication cable assembly 275B at an area 276 of the vehicle 205 that may be easily accessible by a technician.

Within these access areas, a technician may connect a diagnostic equipment in order to test the operation of the associated subsystems. For example, with regard to access area 226, a technician may connect the diagnostic equipment to cable assembly 225A to test the body control operation of the central controller 210 via the cable assembly 225A. Similarly, at such access area 226, a technician may connect a diagnostic equipment to cable assembly 225B to test the body control operation of the body control unit 230 via the cable assembly 225B.

With regard to access area 236, a technician may connect a diagnostic equipment to cable assembly 235A to test the engine control operation of the central controller 210 via the cable assembly 235A. Similarly, at such access area 226, a technician may connect a diagnostic equipment to cable assembly 235B to test the engine control operation of the engine control unit 240 via the cable assembly 235B.

With regard to access area 246, a technician may connect a diagnostic equipment to cable assembly 245A to test the sensor operation of the central controller 210 (with respect to sensor 250) via the cable assembly 235A. Similarly, at such access area 246, a technician may connect a diagnostic equipment to cable assembly 245B to test the sensing operation of the sensor 250 via the cable assembly 245B.

With regard to access area 276, a technician may connect a diagnostic equipment to cable assembly 275A to test the assisted/autonomous driving operation of the central controller 210 via the cable assembly 275A. Similarly, at such access area 276, a technician may connect a diagnostic equipment to cable assembly 275B to test the assisted/autonomous driving operation of the assisted/autonomous driving unit 270 via the cable assembly 275B.

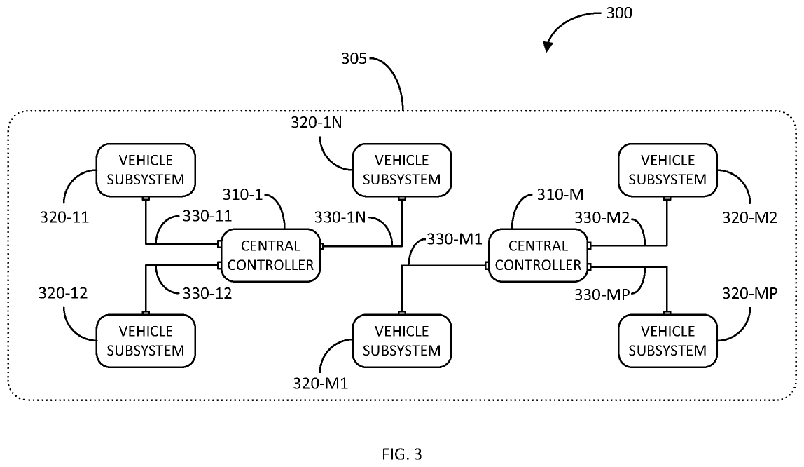

FIG. 3 illustrates a block diagram of another exemplary vehicle data communication system 300 in accordance with another aspect of the disclosure. As discussed above, the vehicle data communication systems 100 and 200 need not be limited to automobile applications. Similar systems may be employed in other types of vehicles, such as airplanes, helicopters, buses, trains, boats, ships, etc. Accordingly, the vehicle data communication system 300 is deployed in a general vehicle 305, which could encompass any type of vehicle.

The vehicle communication system 300 may include a first cluster of subsystems and controller (identified with suffix number “1”), such as central controller 310-1 and associated subsystems 320-11, 320-12 . . . to 320-1N (where N may be an integer of one or more). The subsystems 320-11, 320-12 . . . to 320-1N are data communicatively coupled to the central controller 310-1 via a set of optical data communication cable assemblies 330-11, 330-12 . . . to 330-1N, respectively. Each of the optical data communication cable assemblies may include a set of two or more cascaded cables assemblies. The first cluster of subsystems and controller may be configured to control a specific operation of the vehicle 305, e.g., engine, body, driving, infotainment, etc.

The vehicle communication system 300 may include an Mth cluster of subsystems and controller (identified with suffix number “M”, where M is an integer of two or more), such as central controller 310-M and associated subsystems 320-M1, 320-M2 . . . to 320-MP (where P may be an integer of one or more). The subsystems 320-M1, 320-M2 . . . to 320-MP are data communicatively coupled to the central controller 310-M via a set of optical data communication cable assemblies 330-M1, 330-M2 . . . to 330-MP, respectively. Each of the optical data communication cable assemblies may include a set of two or more cascaded cables assemblies. The Mth cluster of subsystems and controller may be configured to control another specific operation of the vehicle 305, which may be a different operation than that of the 1st cluster or the same if a redundant system is required.

The following goes into more details into various exemplary implementations of the optical data communication cables that may be used in vehicle data communication systems, such as the ones previously described.

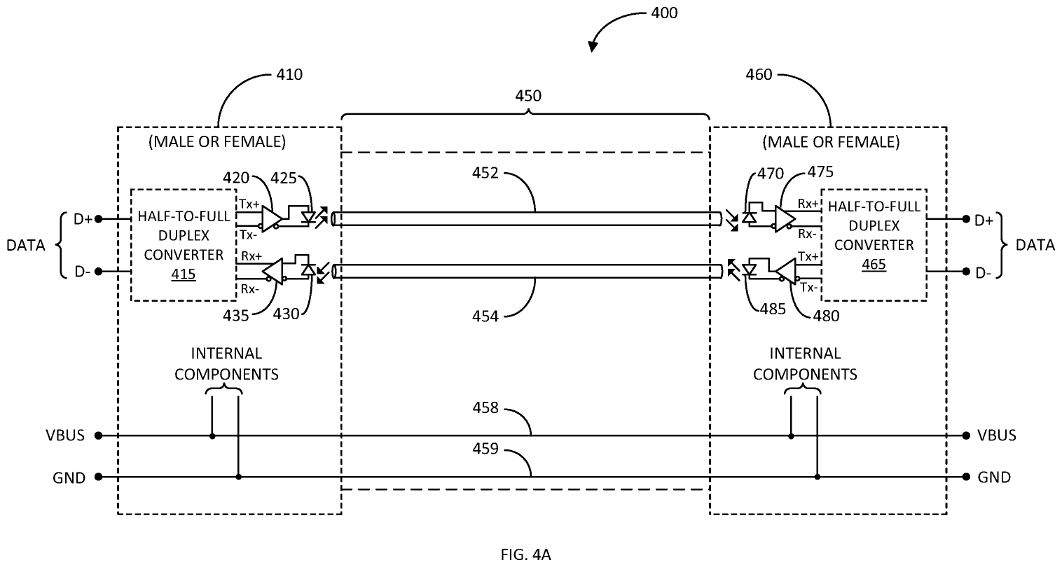

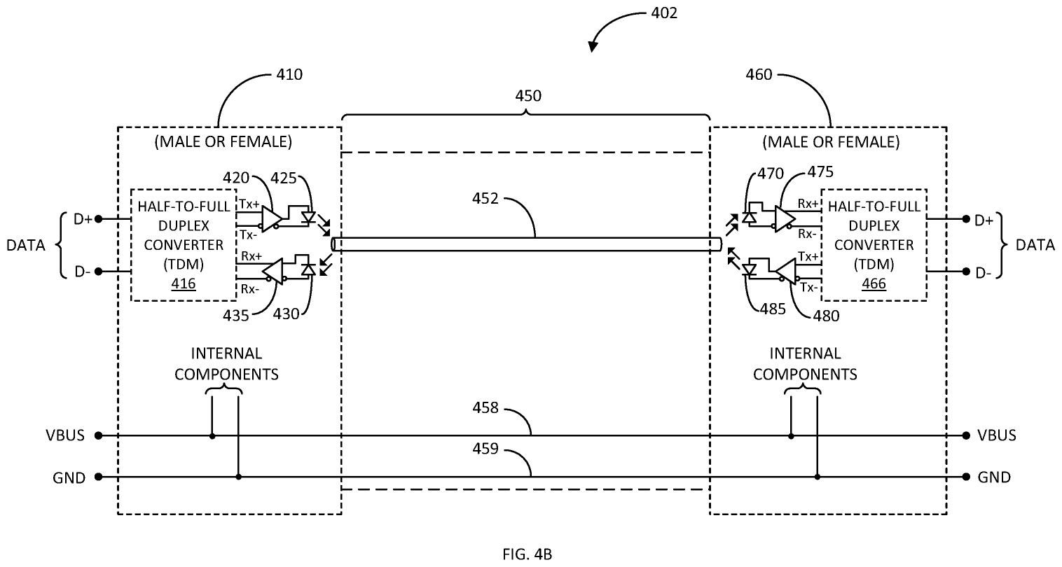

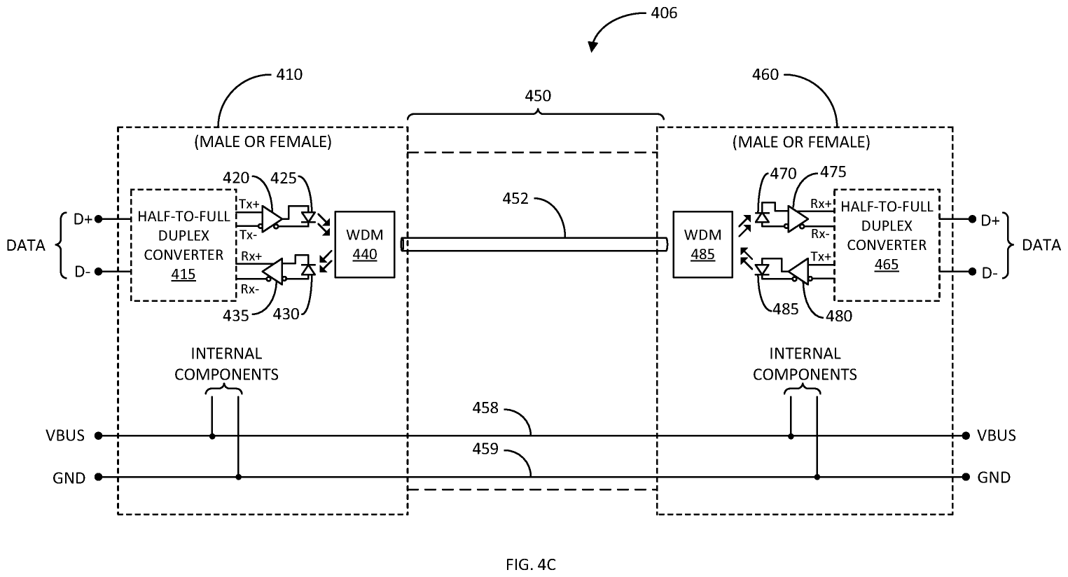

FIG. 4A illustrates a block/schematic diagram of an exemplary data communication cable assembly 400 configured for full-duplex data transmission over optical transmission mediums in accordance with another aspect of the disclosure. The data communication cable assembly 400 may be used in a vehicle or other type of data communication application. In the example described herein, a Universal Serial Bus (USB) compliant cable is used to exemplify the cable concepts. However, it shall be understood that the data communication cable assembly 400 may be configured for other types of data transmission, such as those compliant with High Definition Multimedia Interface (HDMI), DisplayPort, Digital Video Interface (DVI), and others.

In particular, the data communication cable assembly 400 includes a first connector 410, a cable 450, and a second connector 460. The cable 450 is securely attached to the first and second connectors 410 and 460 at opposite ends, respectively. The first connector 410 may be configured to mate with a connector of a first vehicle subsystem. The second connector 460 may be configured to mate with a connector of a second vehicle subsystem. Typically, the first and second connectors 410 and 460 may each be configured as the same mating type (male or female) connector, and the corresponding connectors on the first and second vehicle subsystems may each be configured as the opposite mating type (female or male) connector, respectively.

The first connector 410 includes a first half-to-full duplex converter 415 configured to send and/or receive uplink and/or downlink differential data signal D+/D− to and/or from the first vehicle subsystem in a half- or full-duplex manner. The first connector 410 further includes a laser diode driver (LDD) 420 configured to receive the downlink differential data signal Tx+/Tx−, and generate a drive signal for a laser diode (LD) 425. The LD 425, in turn, generates an optical downlink data signal modulated with the data signal for transmission to the second vehicle subsystem via an optical transmission medium 452 (e.g., an optical fiber) and the second connector 460.

The first connector 410 further includes a photo diode or detector (PD) 430 configured to receive an uplink optical data signal modulated with a data signal originating from the second vehicle subsystem via the second connector 460 and an optical transmission medium 454 (e.g., an optical fiber). The PD 430 converts the optical uplink data signal into a modulated current. The first connector 410 further includes a transimpedance amplifier (TIA) 435 configured to convert the modulated current into an uplink differential data voltage signal Rx+/Rx−. The half-to-full duplex converter 415 sends the uplink differential data voltage signal Rx+/Rx− as a compliant electrical uplink data signal D+/D− to the first vehicle subsystem.

In the case of a USB-compliant cable, the first connector 410 may also send or receive a power signal, such as VBUS and ground (GND), to or from the first vehicle subsystem. The power signal (VBUS/GND) may be used to provide power to internal components of the data communication cable assembly 400, such as the first half-to-full duplex converter 415, the LDD 420, the LD 425, the PD 430, and the TIA 435. The power signal (VBUS/GND) may be sent to or received from the second connector 460 via electrical wires 458 and 459 of the cable 450, respectively.

The second connector 460 includes a second half-to-full duplex converter 465 configured to send and/or receive downlink and/or uplink differential data signal D+/D− to and/or from the second vehicle subsystem in a half- or full-duplex manner. The second connector 460 further includes a photo diode or detector (PD) 470 configured to receive a downlink optical data signal modulated with a data signal originating from the first vehicle subsystem via the first connector 410 and the optical transmission medium 452. The PD 470 converts the modulated optical signal into a modulated current. The second connector 460 further includes a transimpedance amplifier (TIA) 475 configured to convert the modulated current into a downlink differential data voltage signal Rx+/Rx−. The second half-to-full duplex converter 465 sends the downlink differential data voltage signal Rx+/Rx− as a compliant electrical downlink data signal D+/D− to the second vehicle subsystem.

The second connector 460 further includes a laser diode driver (LDD) 480 configured to receive the electrical uplink data signal Tx+/Tx−, and generate a drive signal for a laser diode (LD) 485. The LD 485, in turn, generates an uplink optical data signal modulated with the data signal for transmission to the first vehicle subsystem via the optical transmission medium 454 and the first connector 410.

In the case of a USB-compliant cable, the second connector 460 may also send or receive a power signal, such as VBUS and ground (GND), to or from the second vehicle subsystem. The power signal (VBUS/GND) may be used to provide power to internal components of the data communication cable assembly 400, such as the second half-to-full duplex converter 465, the LDD 480, the LD 485, the PD 470, and the TIA 475. The power signal (VBUS/GND) may be sent to or received from the first connector 410 via the electrical wires 458 and 459 of the cable 450, respectively.

The conversion from electrical-to-optical signal domain and vice-versa allows the data communication cable assembly 400 to transmit data at higher data rates with less electromagnetic interference (EMI) as compared to wire-based data communication cables. This facilitates the data communication cable assembly 400 meeting data rate and EMC requirements specified by appropriate vehicle regulation entities.

FIG. 4B illustrates a block/schematic diagram of another exemplary data communication cable assembly 402 configured for half-duplex data transmission over at least one optical transmission medium (e.g., an optical fiber) in accordance with another aspect of the disclosure. The data communication cable assembly 402 is similar to that of data communication cable assembly 400, and includes many similar elements as indicated by the same reference numbers. The data communication cable assembly 402 differs from data communication cable assembly 400 in that cable assembly 402 is configured for half-duplex, time division multiplexing (TDM) data transmission over an optical transmission medium. Accordingly, the focus of the following discussion of data communication cable assembly 402 is its difference with data communication cable assembly 400.

In particular, the first connector 410 includes a half-to-full duplex converter (TDM) 416 configured to receive a downlink differential data signal D+/D− from the first vehicle subsystem, and process the signal for transmission to the second vehicle subsystem via an optical transmission medium 452 and the second connector 460. The half-to-full duplex converter (TDM) 416 is also configured to receive an uplink differential data signal D+/D− from the second vehicle subsystem via the second connector 460 and the optical transmission medium 452. The processing of the differential data signal D+/D− by the first half-to-full duplex converter (TDM) 416 is similar to that of the first half-to-full duplex converter 415 previously discussed, e.g., receiving a downlink data signal from and sending an uplink data signal to the first vehicle subsystem in a half- or full-duplex manner.

However, in this case, the first half-to-full duplex converter (TDM) 416 transmits and receives the uplink and downlink differential data signals D+/D− via the optical transmission medium 452 in a time division multiplexed (TDM) manner. That is, within a first time interval, the first half-to-full duplex converter (TDM) 416 including the LDD 420 and the LD 425 transmits the downlink optical data signal D+/D− via the optical transmission medium 452, and within a second time interval (substantially non-overlapping with the first time interval) the first half-to-full duplex converter (TDM) 416 including the PD 430 and TIA 435 receive the uplink optical data signal D+/D− from optical transmission medium 452.

Similarly, the second connector 460 includes a second half-to-full duplex converter (TDM) 466 configured to receive a downlink differential data signal D+/D− from the first vehicle subsystem via the first connector 410 and cable 450, and process the signal for transmission to the second vehicle subsystem. The second half-to-full duplex converter (TDM) 466 is also configured to receive an electrical uplink data signal D+/D− from the second vehicle subsystem and process the signal for transmission to the first vehicle subsystem via the optical transmission medium 452 and the first connector 410. The processing of the differential data signal D+/D− by the second half-to-full duplex converter (TDM) 466 is similar to that of the first half-to-full duplex converter (TDM) 465 previously discussed, e.g., receiving an electrical uplink data signal from and sending an electrical downlink data signal to the second vehicle subsystem in a half- or full-duplex manner.

However, in this case, the second half-to-full duplex converter (TDM) 466 transmits and receives the uplink and downlink data signals D+/D− via the optical transmission medium 452 in a time division multiplexed (TDM) manner. That is, within a first time interval, the second half-to-full duplex converter (TDM) 466 including the LDD 480 and the LD 485 transmits an uplink optical data signal D+/D− via the optical transmission medium 452, and within a second time interval (substantially non-overlapping with the first time interval) the second half-to-full duplex converter (TDM) 466 including the PD 470 and TIA 475 receive the optical downlink data signal D+/D-via the optical transmission medium 452.

FIG. 4C illustrates a block/schematic diagram of another exemplary data communication cable assembly 406 configured for full-duplex data transmission over at least one optical transmission electrical medium (e.g., an optical fiber) in accordance with another aspect of the disclosure. The data communication cable 406 is similar to that of data communication cable assemblies 400 and 402, and includes many similar elements as indicated by the same reference numbers. The data communication cable assembly 406 differs from data communication cable assemblies 400 and 402 in that cable assembly 406 is configured for full-duplex, wavelength division multiplexing (WDM) data transmission over an optical transmission medium. Accordingly, the focus of the following discussion of data communication cable assembly 406 is its difference with data communication cable assemblies 400 and 402.

In the case of data communication cable assembly 406, the half-to-full duplex converter 415 transmits and receives downlink and uplink differential data signals D+/D− via the optical transmission medium 452 in a wavelength division multiplexed (WDM) manner. That is, within a first wavelength range, the half-to-full duplex converter 415 including the LDD 420, the LD 425, and a wavelength division multiplexer (WDM) 440 transmit the downlink optical differential data signal D+/D− via the optical transmission medium 452, and within a second wavelength range (substantially non-overlapping with the first wavelength range), the half-to-full duplex converter 415 including the WDM 440, PD 430, and the TIA 435 receive the uplink optical differential data signal D+/D− from optical transmission medium 452.

Similarly, the second half-to-full duplex converter (TDM) 465 transmits and receives the uplink and downlink differential data signals D+/D− via the optical transmission medium 452 in a wavelength division multiplexed (WDM) manner. That is, within a first wavelength range, the second half-to-full duplex converter (TDM) 465 including the LDD 480, laser diode 485, and a wavelength division multiplexer (WDM) 485 transmits an uplink optical differential data signal D+/D− via the optical transmission medium 452, and within a second wavelength range (substantially non-overlapping with the first wavelength range), the second half-to-full duplex converter 466 including the WDM 485, PD 470, and TIA 475 receive the downlink optical differential data signal D+/D− via the optical transmission medium 452.

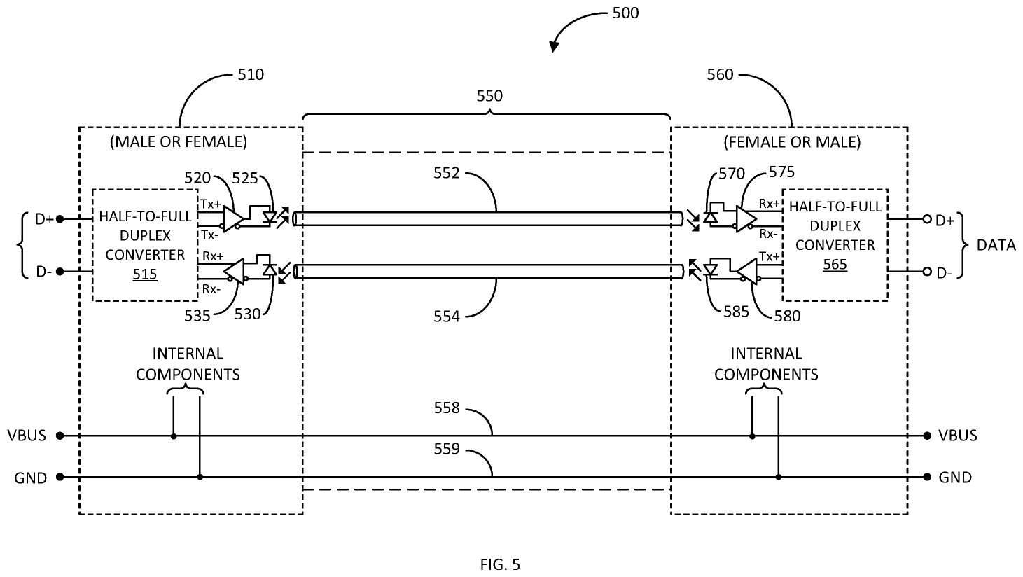

FIG. 5 illustrates a block/schematic diagram of an exemplary cascadable data communication cable assembly 500 including optical transmission mediums in accordance with another aspect of the disclosure. The cascadable data communication cable assembly 500 is similar to that of data communication cable assembly 400 with similar elements identified by the same reference numbers except the most significant digital (MSD) is a “5” instead of a “4”. However, it shall be understood that the cascadable data communication cable assembly 500 may be configured similar to data communication cable assemblies 402 and 406.

In particular, the cascadable data communication cable assembly 500 includes a first connector 510 with a half-to-full duplex converter 515, LDD 520, LD 525, PD 530, and TIA 535, a cable 550 with one or more optical transmission mediums 552 and 554, and a second connector 560 with a half-to-full duplex converter 565, LDD 580, LD 585, PD 570, and TIA 575. The data communication cable assembly 500 further includes power signal (VBUS, GND) electrical conductors in the first connector 510, electrical wires 558 and 559 in the cable 550, and electrical conductors in the second connector 560.

The cascadable communication cable assembly 500 differs from data communication cable 400 in that the second connector 560 is of the opposite mating type (female or male) as that of the first connector 510. This feature allows a set of two or more cable assemblies 500 to be cascaded to form a longer length cable. Such as by connecting the second connector of one of the cables to the first connector of the cascaded or following cable, and so on. An example of a vehicle data communication system with a set of cascaded data communication cable assemblies is described below.

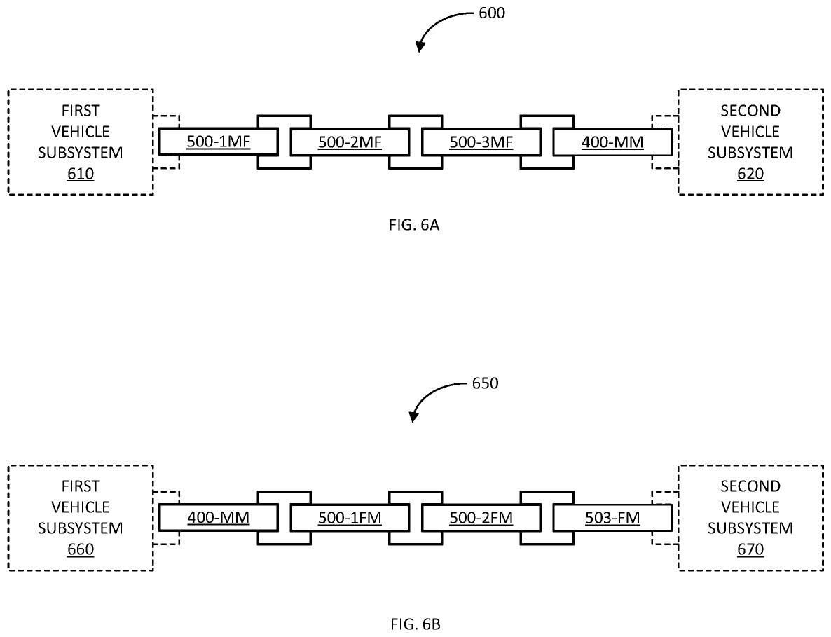

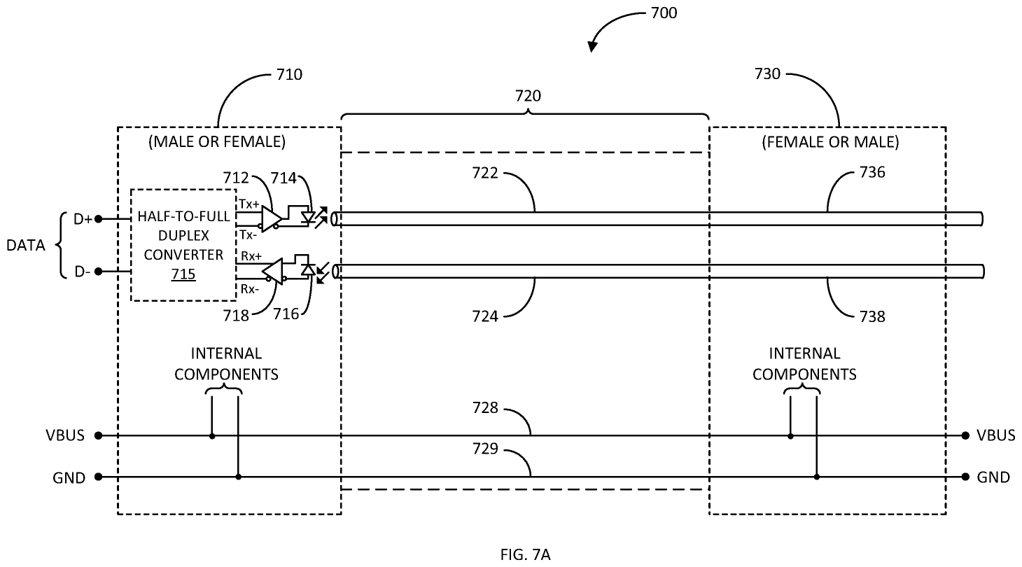

FIG. 6A illustrates a block diagram of an exemplary vehicle data communication system 600 including a set of cascaded data communication cable assemblies in accordance with another aspect of the disclosure. The vehicle data communication system 600 includes a first vehicle subsystem 610.

The data communication system 600 further includes two or more data communication cable assemblies 500-1MF, 500-2MF, and 500-3MF (e.g., three or any number as desired) cascaded to form a longer cable. Each of the cable assemblies 500-1MF, 500-2MF, and 500-3MF may be configured similar to data communication cable assembly 500.

The data communication cable assembly 500-1MF includes a first male connector mated with a female connector of the first vehicle subsystem 610. The data communication cable assembly 500-2MF includes a first male connector mated with a second female connector of data communication cable assembly 500-1MF. The data communication cable assembly 500-3MF includes a first male connector mated with a second female connector of data communication cable assembly 500-2MF. As the data communication cable 500-3MF has a second female connector, it may not be able to mate with the female connector of a second vehicle subsystem 620.

Accordingly, the data communication system 600 includes a data communication cable assembly 400-MM that includes both male first and second connectors. This allows the data communication cable assembly 400-MM to mate with the second female connector of the data communication cable assembly 500-3MF and the female connector of the second vehicle subsystem 620. The data communication cable assembly 400-MM may be configured similar to data communication cable assembly 400 (or 402 or 406).

Thus, the cables 500-1MF, 500-2MF, 500-3MF, and 400-MM may be cascadable or daisy-chained to form longer length cables in order to meet the distance requirements for desirably-placed devices, as well as to provide connection points for diagnostic equipment within access areas, as previously discussed. As the cables 500-1MF, 500-2MF, 500-3MF, and 400-MM include low loss and distortion optical transmission mediums, the data signal communicated between the first and second vehicle subsystems 610 and 620 may be successfully transmitted and recovered. Further, as discussed, since the primary transmission medium is optical, these cascaded cables produce less electromagnetic interference (EMI) compared to electrical-wire counterparts.

FIG. 6B illustrates a block diagram of an exemplary vehicle data communication system 650 including a set of cascaded data communication cable assemblies in accordance with another aspect of the disclosure. The vehicle data communication system 650 includes a first vehicle subsystem 660.

The vehicle data communication system 650 further includes two or more data communication cable assemblies 400-MM, 500-1FM, 500-2FM, and 500-3FM (e.g., four or any number as desired) cascaded to form a longer cable. The data communication cable assembly 400-MM may be configured similar to data communication cable assembly 400 (or 402 or 406). Each of the cable assemblies 500-1MF, 500-2MF, and 500-3MF may be configured similar to data communication cable assembly 500.

The data communication cable assembly 400-MM includes a first male connector mated with a female connector of the first vehicle subsystem 660. The data communication cable assembly 500-1FM includes a first female connector mated with a second male connector of data communication cable assembly 400-MM. The data communication cable assembly 500-2FM includes a first female connector mated with a second male connector of data communication cable assembly 500-1FM. The data communication cable assembly 500-3FM includes a first female connector mated with a second male connector of data communication cable assembly 500-2MF. The data communication cable 500-3FM includes a second male connector mated with the female connector of a second vehicle subsystem 670.

Thus, the cables 400-MM, 500-1FM, 500-2FM, and 500-3FM may be cascadable or daisy-chained to form longer length cables in order to meet the distance requirements for desirably-placed devices, as well as to provide connection points for diagnostic equipment within access areas, as previously discussed. As the cables 400-MM, 500-1FM, 500-2FM, and 500-3FM include low loss and distortion optical transmission mediums, the data signal communicated between the first and second vehicle subsystems 660 and 670 may be successfully transmitted and recovered. Further, as discussed, since the primary transmission medium is optical, these cascaded cables produce less electromagnetic interference compared to electrical-wire counterparts.

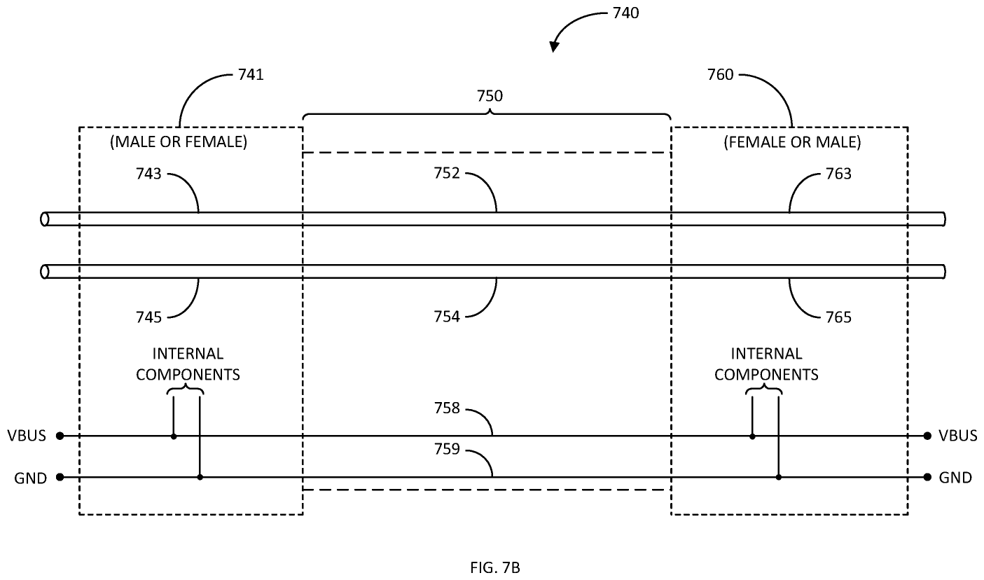

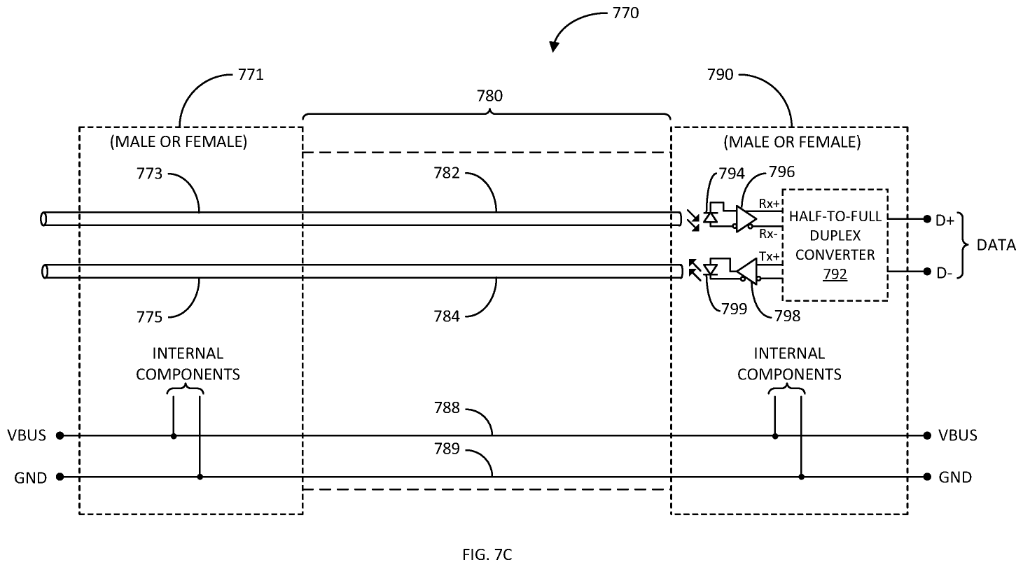

FIG. 7A illustrates a block/schematic diagram of an exemplary cascadable data communication cable assembly 700 including one or more optical transmission mediums in accordance with another aspect of the disclosure. The cascadable data communication cable assembly 700 includes a first connector similar to that of data communication cable assembly 400, but a second connector that is in the optical domain for data transmission. Thus, the cascadable data communication cable assembly 700 includes a first connector 710 with a half-to-full duplex converter 715, LDD 712, LD 714, PD 716, and TIA 718, and a cable 720 with one or more optical transmission mediums 722 and 724. The data communication cable assembly 700 further includes power signal (VBUS, GND) electrical conductors in the first connector 710, electrical wire mediums 728 and 729 in the cable 720, and electrical conductors in the second connector 730.

The cascadable data communication cable assembly 700 differs from data communication cable assembly 400 in that the second connector 730 is of the opposite mating type (female or male) as that of the first connector 710. This feature facilitates cascading the cable assemblies, as discussed in more detail herein. Another difference between data communication cable assembly 700 and data communication cable assembly 400 is that the second connector 730 continues in optical domain. In this regard, the optical transmission mediums 722 and 724 of the cable 730 may extend into and through the second connector 730 for optical connection to other optical transmission mediums in the following cable.

FIG. 7B illustrates a block/schematic diagram of another exemplary cascadable data communication cable assembly 740 including one or more optical transmission mediums in accordance with another aspect of the disclosure. The cascadable data communication cable assembly 740 includes first and second connectors that are in the optical domain for data transmission. The data communication cable assembly 740 further includes power signal (VBUS, GND) electrical conductors in the first connector 741, electrical wires 758 and 759 in the cable 750, and electrical conductors in the second connector 760.

More specifically, the data communication cable assembly 740 includes a first connector 741 (male or female) including optical transmission mediums 743 and 745 for optically coupling to optical transmission mediums of a data communication cable assembly to which it mates on the left side of the cable assembly 740. The optical data signals may be transmitted between the first and second connectors 741 and 760 via optical transmission mediums 752 and 754 of the cable 750, respectively. Similarly, the second connector 760 (female or male) includes optical transmission mediums 763 and 765 for optically coupling to optical transmission mediums of a data communication cable assembly to which it mates on the right side of the cable assembly 740. The sets of optical transmission mediums 743/752/763 and 745/754/765 may each be

FIG. 7C illustrates a block/schematic diagram of another exemplary cascadable data communication cable assembly 770 including one or more optical transmission mediums in accordance with another aspect of the disclosure. The cascadable data communication cable assembly 770 includes a first connector similar to that of data communication cable assembly 740, and a second connector similar to that of data communication cable assembly 400 (but of the opposite mating type). The data communication cable assembly 770 further includes power signal (VBUS, GND) electrical conductors in the first connector 771, electrical wires 788 and 789 in the cable 780, and electrical conductors in the second connector 790.

More specifically, the data communication cable assembly 770 includes a first connector 771 (male or female) including optical transmission mediums 773 and 775 for optically coupling to optical transmission mediums of a data communication cable assembly to which it mates on the left side of the cable assembly 740.

The second connector 790 (male or female) includes a half-to-full duplex converter 792 configured to send and/or receive downlink and uplink differential data signals D+/D− to and/or from the second vehicle subsystem. The second connector 790 further includes a photo diode or detector (PD) 794 configured to receive a downlink optical signal modulated with a data signal originating from the first vehicle subsystem via the first connector 771 and the optical transmission medium 782. The PD 794 converts the modulated optical signal into a modulated current. The second connector 790 further includes a transimpedance amplifier (TIA) 796 configured to convert the modulated current into a downlink differential data voltage signal Rx+/Rx−. The half-to-full duplex converter 792 sends the differential data voltage signal Rx+/Rx− as an electrical downlink data signal D+/D− to the second vehicle subsystem.

The second connector 790 further includes a laser diode driver (LDD) 798 configured to receive an electrical uplink data signal Tx+/Tx−, and generate a drive signal for a laser diode (LD) 799. The LD 799, in turn, generates an optical uplink data signal modulated with the data signal for transmission to the first vehicle subsystem via the optical transmission medium 784 and the first connector 771.

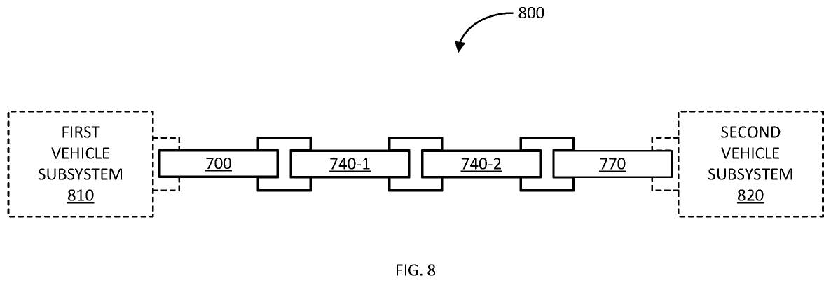

FIG. 8 illustrates a block diagram of an exemplary vehicle data communication system 800 including a set of cascaded data communication cable assemblies in accordance with another aspect of the disclosure. The vehicle data communication system 800 includes a first vehicle subsystem 810.

The vehicle data communication system 800 further includes two or more data communication cable assemblies 700, 740-1 and 740-2 (e.g., two or any other number), and 770 cascaded to form a longer cable. The data communication cable assembly 700 on the left may be connected to the first vehicle subsystem 710. The left-middle data communication cable assembly 740-1 is connected to the left data communication cable assembly 700 and to the right-middle data communication cable assembly 740-2. As the right-middle data communication cable 740-2 may have a right female connector, it may not be able to mate with the female connector of a second vehicle subsystem 820.

Accordingly, the data communication system 800 includes a right-most data communication cable assembly 770 that includes both male first and second connectors. This allows the data communication cable assembly 770 to mate with the female connector of the right-middle data communication cable assembly 740-2 and the female connector of the second vehicle subsystem 820. Thus, the cable assemblies 700, 740-1, 740-2, and 770 may be cascadable or daisy-chained to form longer length cables in order to meet the distance requirements for desirably-placed devices, as well as to provide connection points for diagnostic equipment within access areas, as previously discussed. As the cable assemblies 700, 740-1, 740-2, and 770 include low loss and distortion optical transmission mediums, the data signal communicated between the first and second vehicle subsystems 810 and 820 may be successfully transmitted and recovered. Further, as discussed, since the primary transmission medium is optical, these cascaded cables produce less electromagnetic interference compared to electrical-wire counterparts.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

What is claimed is:

1. A vehicle data communication system, comprising:
a first vehicle subsystem;
a second vehicle subsystem; and
a data communication cable assembly, comprising:
a first connector connected to the first vehicle subsystem;
a second connector connected to the second vehicle subsystem; and
a cable including opposite ends securely attached to the first and second connectors, respectively, wherein the cable comprises one or more optical transmission mediums configured to transmit a first optical data signal from the first connector to the second connector.

2. The vehicle data communication system of claim 1, wherein the first connector comprises a circuit configured to convert an electrical data signal received from the first vehicle subsystem into the first optical data signal.

3. The vehicle data communication system of claim 2, wherein the circuit comprises:
a laser diode driver (LDD) configured to generate a laser drive signal based on the electrical data signal; and
a laser diode configured to generate the first optical data signal based on the laser drive signal.

4. The vehicle data communication system of claim 1, wherein the one or more optical transmission mediums is configured to transmit a second optical data signal from the second connector to the first connector.

5. The vehicle data communication system of claim 4, wherein the first connector comprises a circuit configured to convert the second optical data signal into an electrical data signal for providing to the first vehicle subsystem.

6. The vehicle data communication system of claim 5, wherein the circuit comprises a photo diode or detector (PD) and transimpedance amplifier (TIA) configured to convert the second optical data signal into the electrical data signal.

7. The vehicle data communication system of claim 4, wherein the first connector comprises:
a first circuit configured to convert a first electrical data signal received from the first vehicle subsystem into the first optical data signal;
a second circuit configured to convert the second optical data signal into a second electrical data signal; and
a half-to-full duplex converter configured to receive the first electrical data signal from the first vehicle subsystem and the send of the second electrical data signal to the first vehicle subsystem.

8. The vehicle data communication system of claim 4, wherein the first connector comprises:
a first circuit configured to convert a first electrical data signal received from the first vehicle subsystem into the first optical data signal; and
a second circuit configured to convert the second optical data signal into a second electrical data signal;
wherein the first and second circuits are configured to transmit and receive the first and second optical data signals via the one or more optical transmission mediums in a time-division multiplex (TDM) manner, respectively.

9. The vehicle data communication system of claim 4, wherein the first connector comprises:
a first circuit configured to convert a first electrical data signal received from the first vehicle subsystem into the first optical data signal; and
a second circuit configured to convert the second optical data signal into a second electrical data signal;
wherein the first and second circuits are configured to transmit and receive the first and second optical data signals via the one or more optical transmission mediums in a wavelength-division multiplex (WDM) manner, respectively.

10. The vehicle data communication system of claim 4, wherein the second connector comprises a circuit configured to convert an electrical data signal received from the second vehicle subsystem into the second optical data signal.

11. The vehicle data communication system of claim 10, wherein the circuit comprises:
a laser diode driver (LDD) configured to generate a laser drive signal based on the electrical data signal; and
a laser diode configured to generate the second optical data signal based on the laser drive signal.

12. The vehicle data communication system of claim 1, wherein the second connector comprises a circuit configured to convert the first optical data signal into an electrical data signal for providing to the second vehicle subsystem.

13. The vehicle data communication system of claim 12, wherein the circuit comprises a photo diode or detector (PD) and transimpedance amplifier (TIA) configured to convert the first optical data signal into the electrical data signal.

14. The vehicle data communication system of claim 1, wherein the cable comprises one or more electrical wire mediums configured to route a power signal between the first and second vehicle subsystems.

15. A vehicle data communication system, comprising:
a first vehicle subsystem;
a second vehicle subsystem;
a first data communication cable assembly, comprising:
a first connector connected to the first vehicle subsystem;
a second connector; and
a first cable including opposite ends securely attached to the first and second connectors, respectively, wherein the first cable comprises a first set of one or more optical data transmission mediums configured to transmit a first set of one or more optical data signals between the first and second connectors; and
a second data communication cable assembly, comprising:
a third connector;
a fourth connector connected to the second vehicle subsystem; and
a second cable including opposite ends securely attached to the third and fourth connectors, respectively, wherein the second cable comprises a second set of one or more optical data transmission mediums configured to transmit the first set of one or more optical data signals or a second set of one or more data signals between the third and fourth connectors.

16. The vehicle data communication system of claim 15, wherein the second connector is connected to the third connector.

17. The vehicle data communication system of claim 15, wherein the first connector comprises a circuit configured to convert an electrical data signal received from the first vehicle subsystem into the first set of one or more optical data signals.

18. The vehicle data communication system of claim 15, wherein the first connector comprises a circuit configured to convert the first set of one or more optical data signals into an electrical data signal for transmission to the first vehicle subsystem.

19. The vehicle data communication system of claim 15, wherein the first set of one or more optical data transmission mediums are optically coupled to the second set of one or more optical data transmission mediums.

20. The vehicle data communication system of claim 15, wherein the second connector comprises a circuit configured to convert the first set of one or more optical data signals into an electrical data signal.

21. The vehicle data communication system of claim 15, wherein the second connector comprises a circuit configured to convert an electrical data signal based on the second set of one or more optical data signals into the first set of one or more optical data signals.

22. The vehicle data communication system of claim 15, wherein the first and second cables comprises one or more electrical wire mediums configured to route a power signal between the first and second vehicle subsystems.

23. The vehicle data communication system of claim 15, wherein the fourth connector comprises a circuit configured to convert an electrical data signal received from the second vehicle subsystem into the first or second set of one or more optical data signals.

24. The vehicle data communication system of claim 15, wherein the fourth connector comprises a circuit configured to convert the first or second set of one or more optical data signals into an electrical data signal for transmission to the second vehicle subsystem.

25. The vehicle data communication system of claim 15, wherein the third connector comprises a circuit configured to convert the second set of one or more optical data signals into an electrical data signal.

26. The vehicle data communication system of claim 15, wherein the third connector comprises a circuit configured to convert an electrical data signal based on the first set of one or more optical data signals into the second set of one or more optical data signals.
